(19) United States
(12) Patent Application Publication
(10) Pub. No.: US 2025/0105582 A1
(43) Pub. Date: Mar. 27, 2025

(54) INTEGRATED OPTICAL FREQUENCY DISCRIMINATOR

(71) Applicant: CIENA CORPORATION, Hanover, MD (US)

(72) Inventors: Michael Vitic, Chelsea (CA); James S. Harley, Richmond (CA); Tom Luk, Ottawa (CA); Antoine Bois, Québec (CA)

(73) Assignee: CIENA CORPORATION, Hanover, MD (US)

(21) Appl. No.: 18/474,495

(22) Filed: Sep. 26, 2023

(51) Int. Cl. H01S 5/00; G01N 21/39

(52) U.S. Cl. CPC H01S 5/0092; G01N 21/39

(57) ABSTRACT

Aspects of the subject disclosure may include, for example, a device, comprising an optical package, a frequency discriminator configured to provide complementing signals that include phase noise associated with a local oscillator (LO) input, a transimpedance amplifier (TIA) system adapted to provide one or more phase information signals by amplifying a difference of the complementing signals, and an application specific integrated circuit (ASIC) configured to process the one or more phase information signals to derive an estimation of the phase noise, wherein the frequency discriminator is implemented in the optical package and integrated with the TIA system and the ASIC to facilitate avoidance of enhanced equalized phase noise (EEPN). Other embodiments are disclosed.

### FIELD OF THE DISCLOSURE

The subject disclosure relates to integration of an optical frequency discriminator in an intradyne coherent receiver (ICR) or a transmit receive optical silicon integrated circuit (TROSIC).

### BACKGROUND

As technology advances, high performance optical fiber transmission systems continue to evolve with higher bauds and more complex modulation formats.

### BRIEF DESCRIPTION OF THE DRAWINGS

Reference will now be made to the accompanying drawings, which are not necessarily drawn to scale, and wherein:

FIG. 1 is a diagram of a non-limiting example of a communication network in accordance with various aspects described herein.

FIG. 2A illustrates an example ICR that is equipped with a frequency discriminator in accordance with various aspects described herein.

FIG. 2B illustrates an example optical Tx/Rx (transceiver) that is equipped with a frequency discriminator in accordance with various aspects described herein.

FIG. 2C is a block diagram of an example implementation of a frequency discriminator in accordance with various aspects described herein.

FIG. 2D is a block diagram of an example laser differential phase detection circuit in accordance with various aspects described herein.

FIG. 2E is an example receiver circuit architecture in which a transimpedance amplifier extracts phase noise in digital difference and relative intensity noise of a laser in digital sum, in accordance with various aspects described herein.

FIG. 2F is an example receiver circuit architecture in which a transimpedance amplifier extracts (e.g., only) phase noise in digital difference, in accordance with various aspects described herein.

FIG. 2G shows a high-level architecture of a modem receiver with example flows between components, in accordance with various aspects described herein.

### DETAILED DESCRIPTION

With evolving high performance optical fiber transmission systems, equalization-enhanced phase noise (EEPN)-induced distortions become more significant for a given local oscillator (LO) linewidth. As a result of the degradations, tradeoffs may generally need to be made within an achievable systems budget (required optical signal to noise ratio (rOSNR) or dispersion tolerance). One technique to compensate for higher baud or constellation complexity is to utilize lower linewidth lasers (<100 kilohertz (kHz)), such as external cavity nano Integrated Tunable Laser Assembly (ITLA) lasers. However, low linewidth lasers generally use a complex free space optical arrangement of thermally tuned etalons and verniers, which require an extremely high quality factor of the optical cavity. Furthermore, using LOs with <300 kHz linewidths also requires additional components, such as integrated ring resonators or distributed Bragg gratings.

The subject disclosure describes illustrative embodiments of a coherent receiver (e.g., a silicon photonics (SiP) ICR or micro ICR (μICR)) or an optical transceiver (e.g., a TROSiC) that is integrated with an extracted phase noise (EPN) interferometer. In various embodiments, an output of the EPN interferometer may be amplified and digitized to detect the incremental phase of an LO receiver (Rx) laser in the ICR or a shared LO transmit (Tx)/Rx laser in the TROSiC. Integration of the EPN interferometer allows for estimation of the phase, which can be applied to the phase of a digital signal prior to digital signal processing (e.g., digital dispersion compensation, etc.). In one or more embodiments, a (e.g., balanced) transimpedance amplifier (TIA) may also be integrated in (e.g., flip-chipped onto) the ICR/TROSiC, and may be adapted with a difference and/or sum amplifier for amplifying the EPN and/or relative intensity noise (of a laser). In certain embodiments, an Rx application specific integrated circuit (ASIC) may further be integrated with the ICR/TROSiC, and may be adapted with additional analog to digital converters (ADCs) for obtaining the difference and/or sum signals from the TIA and estimating/applying the extracted phase and/or relative intensity noise for cancellation.

Embodiments of the (e.g., monolithic) integration of the EPN interferometer in an ICR/TROSiC along with supporting structures or components (such as balanced photodetectors, the TIA (or EPN receiver), and high speed (e.g., 1 Giga sample/second (GSs)) ADC(s)) advantageously mitigate or eliminate EEPN impairment(s) that can otherwise occur from the interaction of the LO's phase and Rx-based digital dispersion compensation. Utilizing a more integrated (e.g., silicon) receiver/transceiver package, as described herein, allows for the use of LOs with much larger linewidths (e.g., 500+ kHz) without incurring much (if any) system penalty. This also offers simpler and lower loss optical trains, which reduces cost and improves overall performance.

One or more aspects of the subject disclosure include a device, comprising an optical package, a frequency discriminator configured to provide complementing signals that include phase noise associated with a local oscillator (LO) input, a transimpedance amplifier (TIA) system adapted to provide one or more phase information signals by amplifying a difference of the complementing signals, and an application specific integrated circuit (ASIC) configured to process the one or more phase information signals to derive an estimation of the phase noise, wherein the frequency discriminator is implemented in the optical package and integrated with the TIA system and the ASIC to facilitate avoidance of enhanced equalized phase noise (EEPN).

One or more aspects of the subject disclosure include noise cancellation system for integration with an optical package to facilitate avoidance of enhanced equalized phase noise (EEPN), the noise cancellation system comprising a frequency discriminator configured to provide complementing signals that include phase noise associated with a local oscillator (LO) input, a transimpedance amplifier (TIA) system adapted to provide one or more phase information signals by amplifying a difference of the complementing signals, and an application specific integrated circuit (ASIC) configured to process the one or more phase information signals to derive an estimation of the phase noise, wherein the frequency discriminator is implemented in the optical package and integrated with the TIA system and the ASIC.

One or more aspects of the subject disclosure include a method, comprising implementing a frequency discriminator in an optical package, the frequency discriminator being configured to provide complementing signals that include phase noise associated with a local oscillator (LO) input, and integrating a transimpedance amplifier (TIA) system and an application specific integrated circuit (ASIC) with the frequency discriminator to facilitate avoidance of enhanced equalized phase noise (EEPN), wherein the TIA system is adapted to provide one or more phase information signals by amplifying a difference of the complementing signals, and wherein the ASIC is configured to process the one or more phase information signals to derive an estimation of the phase noise.

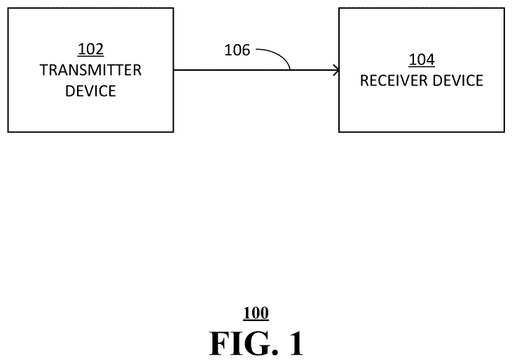

FIG. 1 is a diagram of a non-limiting example of a communication network 100 in accordance with various aspects described herein. The communication network 100 may include at least one transmitter device 102 and at least one receiver device 104. The transmitter device 102 may be capable of transmitting signals over a communication channel, such as a communication channel 106. In one or more embodiments, the transceiver 102 may be a modem. The receiver device 104 may be capable of receiving signals over a communication channel, such as the communication channel 106. In various embodiments, the transmitter device 102 may also be capable of receiving signals and/or the receiver device 104 may also be capable of transmitting signals. Thus, one or both of the transmitter device 102 and the receiver device 104 may be capable of acting as a transceiver.

The communication network 100 may include additional elements not shown in FIG. 1. For example, the communication network 100 may include one or more additional transmitter devices, one or more additional receiver devices, and one or more other devices or elements (e.g., active optical devices (such as optical amplifiers) and/or passive devices (such as multiplexer(s), demultiplexer(s), fiber(s), etc.)) involved in the communication of signals in the fiber-optic communication network 100.

In some embodiments, the signals that are transmitted and received in the communication network 100 may include optical signals and/or electrical signals. For example, the transmitter device 102 may be a first optical transceiver, the receiver device 104 may be a second optical transceiver, and the communication channel 106 may be an optical communication channel. In certain embodiments, one or both of the first optical transceiver and the second optical transceiver may be a coherent modem.

In various embodiments, each optical communication channel in the communication network 100 may include one or more links, where each link may include one or more spans, and where each span may include a length of optical fiber and one or more optical amplifiers. Where the communication network 100 involves the transmission of optical signals, the communication network 100 may include additional optical elements not shown in FIG. 1, such as wavelength selective switches, optical multiplexers, optical de-multiplexers, optical filters, and/or the like.

Various elements and effects in an optical link between two communicating devices may result in the degradation of transmitted signals. That is, optical signals received over optical links can become distorted. Particularly, these signals may suffer from polarization mode dispersion (PMD), polarization dependent loss or gain (PDL or PDG), state of polarization (SOP) rotation, amplified spontaneous emission (ASE) noise, wavelength-dependent dispersion or chromatic dispersion (CD), nonlinear noise from propagation through fiber, and/or other effects. For instance, polarization effects of a fiber link tend to rotate the transmitted polarizations such that, at the receiver, they are neither orthogonal to each other nor aligned with the polarization beam splitter of the optical hybrid. As a result, each of the received polarizations (e.g., downstream of the polarization beam splitter) may contain energy from both of the transmitted polarizations, as well as distortions due to CD, PMD, PDL, etc. These problems may be compounded for polarization-division multiplexed signals in which each transmitted polarization contains a respective data signal. The degree of signal degradation due to noise and nonlinearity may be characterized by a signal-to-noise ratio (SNR) or, alternatively, by a noise-to-signal ratio (NSR). The signals transmitted in the communications network may be representative of digital information in the form of bits or symbols. The probability that bit estimates recovered at a receiver differ from the original bits encoded at a transmitter may be characterized by the Bit Error Ratio (BER). As the noise power increases relative to the signal power, the BER may also increase.

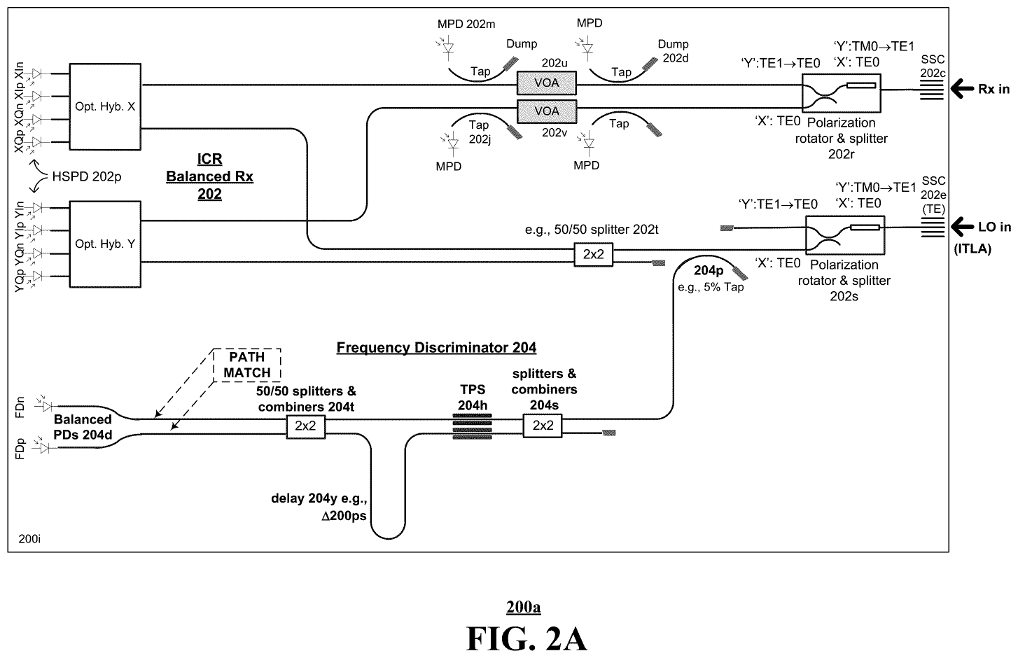

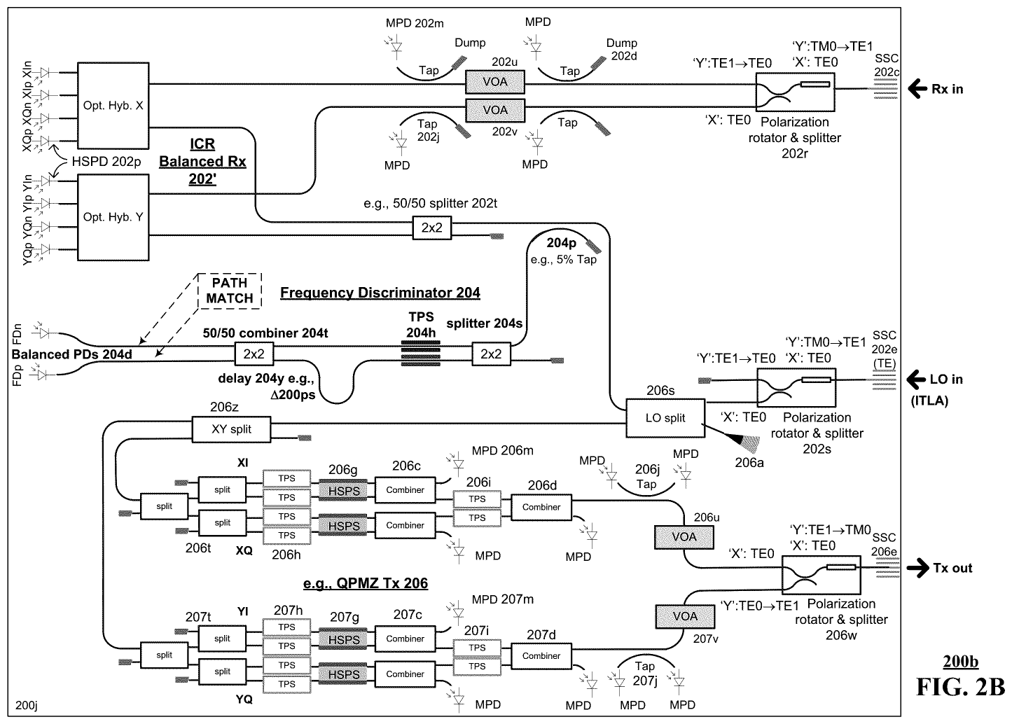

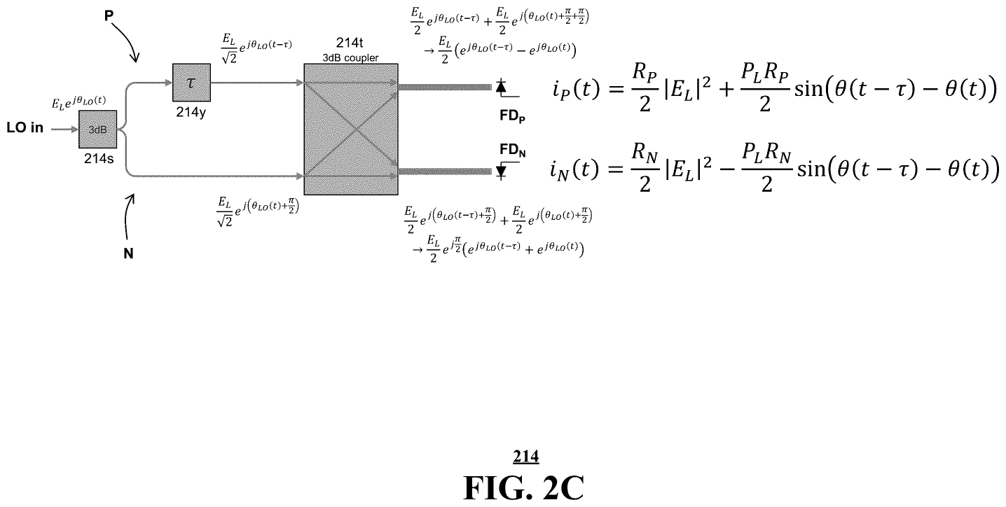

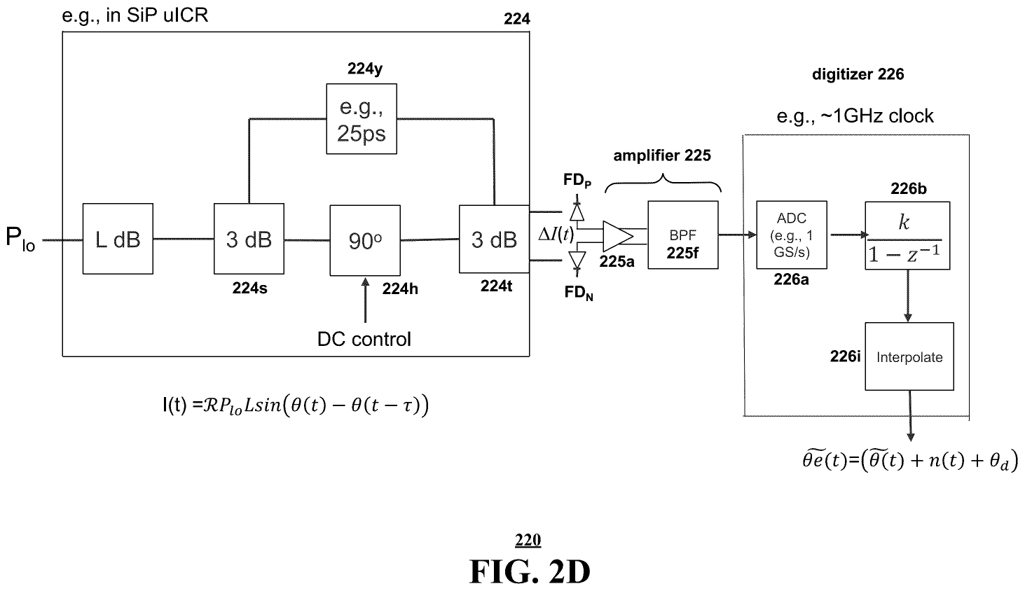

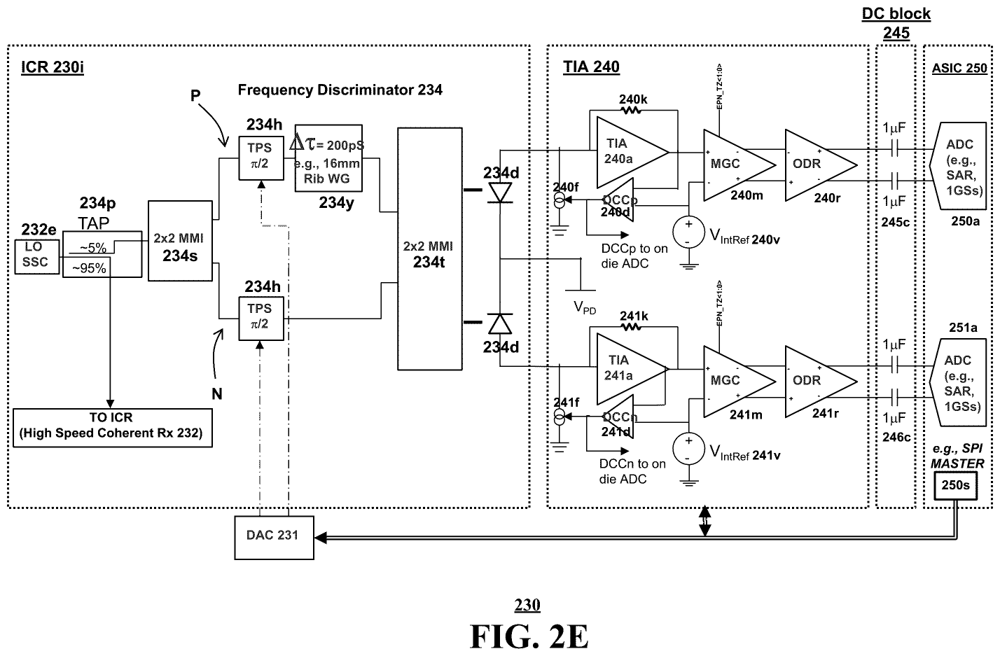

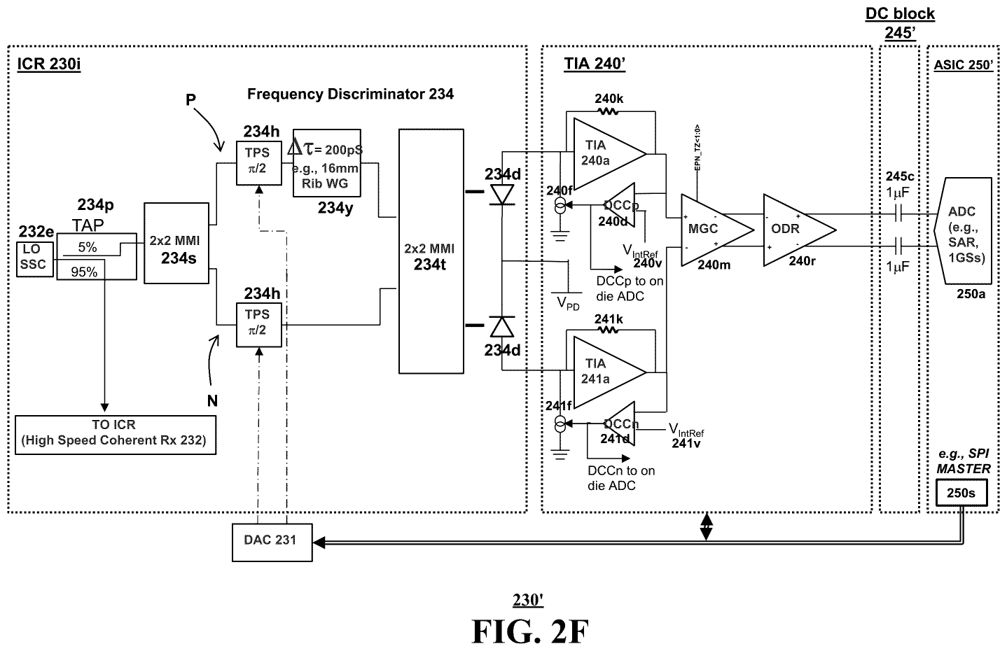

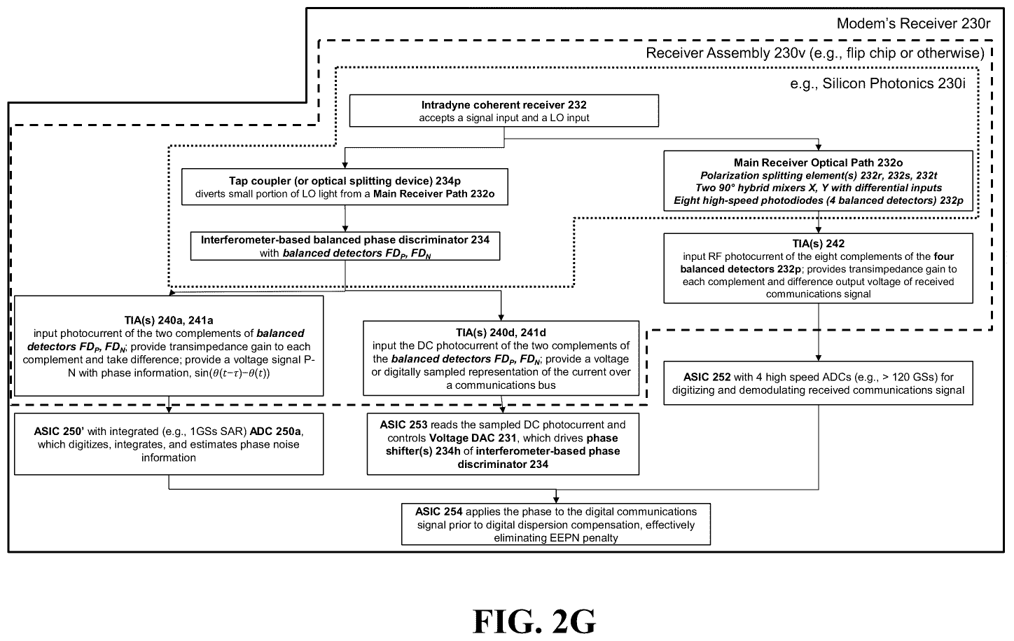

FIG. 2A illustrates an example ICR 200a that is equipped with a frequency discriminator in accordance with various aspects described herein. As shown in FIG. 2A, the ICR 200a may be implemented on a die 200i (e.g., composed of silicon and/or other type of semiconductive material), and may include a balanced receiver 202 and a frequency discriminator 204. Subscripts P (or p) and N (or n) are used herein to refer to balanced components (e.g., photodetectors, etc.) of the receiver 202 and the frequency discriminator 204, where, in two branches, there are non-inverting (P or p) and inverting (N or n) portions of light (e.g., in a push-pull configuration), resulting in a differential signal with a reduced or eliminated common mode that would otherwise be present on the two branches. In various embodiments, the ICR 200a and/or the balanced receiver 202 thereof may be the same as or similar to (or otherwise correspond to) the receiver 104 of FIG. 1, and may be configured to receive an optical signal (Rx in), which may comprise a degraded version of an optical signal generated by a transmitter device (e.g., the transmitter device 102 of FIG. 1). The optical signal generated by the transmitter device may be representative of information bits (also referred to as client bits) which are to be communicated to the balanced receiver 202. The optical signal generated by the transmitter device may be representative of a stream of symbols. According to some examples, the transmitter device may be configured to apply forward error correction (FEC) encoding to the client bits to generate FEC-encoded bits, which may then be mapped to one or more streams of data symbols. The optical signal transmitted by the transmitter device may be generated using any of a variety of techniques, such as frequency division multiplexing (FDM), polarization-division multiplexing (PDM), single polarization modulation, modulation of an unpolarized carrier, mode-division multiplexing, spatial-division multiplexing, Stokes-space modulation, polarization balanced modulation, wavelength division multiplexing (WDM) (where a plurality of data streams is transmitted in parallel, over a respective plurality of carriers, and where each carrier is generated by a different laser), and/or the like.

As shown in FIG. 2A, the ICR 200a may include a spot-size converter (SSC) 202c for coupling optical signals (Rx in) received via one waveguide or in one optical mode into another. The ICR 200a may also (e.g., optionally) include a polarization rotator/splitter 202r for adjusting/splitting Rx in into polarized components. The ICR 200a may further include a SSC 202e for coupling a LO signal (LO in) received via one waveguide or in one optical mode into another. In some embodiments, LO in may be produced by an ITLA, an external cavity laser, etc. The ICR 200a may also include a polarization rotator/splitter 202s for adjusting/splitting LO in into polarized components as well. Transverse Electric (TE) and Transverse Magnetic (TM) modes are electromagnetic wave modes in which the orientation of the electric and magnetic fields are different with respect to the direction of propagation. TE modes have electric fields that are perpendicular to the direction of propagation, whereas TM modes have magnetic fields that are perpendicular to the direction of propagation. In certain embodiments, the optical modes of Rx in and LO in may be converted as shown (e.g., by stripping away TM so that only TE is guided).

According to one example implementation, the polarized components may include orthogonally polarized components corresponding to an X polarization and a Y polarization. The ICR 200a may include various components that couple/lead to an optical hybrid coupler X for the X polarization and an optical hybrid coupler Y for the Y polarization. These components may include variable optical attenuators (VOAs) 202u, 202v for the X. Y polarizations (for adjusting optical power levels), taps 202j (for extracting portions of optical signals for monitoring/diagnostic purposes), dumps 202d (as termination points for optical signals that are no longer needed), monitoring photodetectors (MPD) 202m (for monitoring extracted portions of optical signals), and a splitter (e.g., 50/50 splitter) 202t, as shown.

Photodetectors 202p (which may be high-speed photodetectors) may be configured to convert the optical signals output by the optical hybrids X. Y to analog electrical signals for processing by an Rx ASIC (not shown in FIG. 2A). The frequency difference between the Rx laser and the Tx laser is the Intermediate Frequency, and an offset of that away from nominal can be called fIF. According to one example implementation, the analog signals may include signals corresponding, respectively, to the dimensions XI and XQ (XIₚ, XIₙ, XQₚ, XQₙ) and YI and YQ (YIₚ, YIₙ, YQₚ, YQₙ), where XI and XQ denote the in-phase and quadrature components of the X polarization, and YI and YQ denote the in phase and quadrature components of the Y polarization.

In exemplary embodiments, the frequency discriminator 204 may be an interferometer that includes various components for detecting the incremental phase of the LO laser. As shown in FIG. 2A, the frequency discriminator 204 may include a tap coupler 204p (e.g., a 5% tap or thereabouts, as any greater would divert too much light from the balanced receiver 202) to split a small amount of the light from LO in. The frequency discriminator 204 may also include splitter(s) (e.g., a near 50%/50% splitter, such as a 2×2 multi-mode interferometer (MMI), a directional coupler, a Y-branch, etc.) for splitting the optical path into two paths for the interferometer, a single or pair of thermal phase shifters (TPSs) 204h or other types of phase shifters, an optical delay 204y (e.g., about 200 picoseconds) in one path relative to the other path, combiners/splitters 204t (e.g., where straight and crossed outputs may be used, and again where the coupler may be a 2×2 MMI, a directional coupler, a Y-branch, etc.), and a pair of photodetectors 204d, which may be either individual, totem connected (common cathode/anode) or balanced (common cathode). The configuration of the frequency discriminator 204 may facilitate “beating” of the light between the main path and the delayed path, which, based on the delay length, results in a beating of the light at a given frequency with associated phase noise. As described in more detail below, the frequency discriminator 204 may be integrated with other devices to estimate the detected phase noise and use it to (partially or fully) cancel EPN in the (e.g., digital) signal prior to performing digital dispersion compensation and/or other processing.

For (e.g., optimal or improved) power balancing on the photodetectors 204d, the splitter 204s in the optical path of the interferometer may be chosen to have a 50/50 ratio or a different ratio (e.g., 52/48, etc.). Assuming lossless couplers, where the cross-ratio of the first and second couplers 204s and 204t are presented as 0≤c₁≤1 and 0≤c₂≤1, respectively, where transmission of the lossy delay path is represented as 0≤α≤1, and where the other path (without the delay) is normalized to unity, ideal balancing may achieved with c₁(1−c₂)α+(1−c₁)c₂−c₁c₂α−(1−c₁)(1−c₂)=0. Rewritten as a pair of intersecting lines (−αc₁−c₁+1)(2c₂−1)=0, the solution for the balancing may be c₁=1/(α+1) and c₂=½(i.e., 50/50).

FIG. 2B illustrates an example optical Tx/Rx (transceiver) 200b that is equipped with a frequency discriminator in accordance with various aspects described herein. In exemplary embodiments, the transceiver 200b may be implemented on a die 200j—e.g., as a TROSiC SiP chip or package. As shown in FIG. 2B, the transceiver 200b may include an instance of the frequency discriminator 204 described above with respect to FIG. 2A. Further, the transceiver 200b may include a balanced receiver 202′, which may be similar to or otherwise correspond to the balanced receiver 202 of FIG. 2A. The difference here is that the LO signal is split between the balanced receiver 202′ and a transmitter portion 206. In various embodiments, the transmitter portion 206 may be the same as or similar to (or otherwise correspond to) the transmitter 102 of FIG. 1, and may be configured to transmit an optical signal (Tx out) to a receiver.

The transmitter portion 206 may employ nested Mach-Zehnder (MZ) architecture(s)—i.e., two dual-parallel MZs (DPMZs), each with two inner MZs and one outer MZ—resulting in a quad parallel MZ (QPMZ) modulator. In one or more embodiments, the optical modulator system may be equipped to control four quadrature data signals (i.e., radio frequency (RF) XI, RF XQ, RF YI, RF YQ signals) via a Tx ASIC (not shown in FIG. 2B). Although not shown, in certain embodiments, a single DPMZ (rather than a QPMZ) may be utilized, resulting in a 4-amplitude shift keying (ASK) modulation format for the transmitter portion.

The QPMZ modulator may include an XI modulator, an XQ modulator, and an outer phase modulator (respectively functioning as two inner MZs nested within an outer MZ for the X polarization) as well as a YI modulator, a YQ modulator, and an outer phase modulator (respectively functioning as two inner MZs nested within an outer MZ for the Y polarization). Each MZ may have one or two DC electrodes depending on the implementation of the MZ.

As shown in FIG. 2B, the transmitter portion 206 may obtain a split optical (e.g., laser) signal from an LO splitter 206s (which may be coupled to a grating coupler 206a) for feeding into parallel sets of components in the QPMZ architecture. The laser input may be divided (e.g., via a beam splitter 2062) into X and Y polarizations, where the X polarization may be further divided into an optical I input that is fed into an X-pol I-arm (i.e., the XI modulator) and an optical Q input that is fed into an X-pol Q-arm (i.e., the XQ modulator), and where the Y polarization may be further divided into an optical I input that is fed into a Y-pol I-arm (i.e., the YI modulator) and an optical Q input that is fed into a Y-pol Q-arm (i.e., the YQ modulator). The QPMZ modulator 206 may be capable of independently generating orthogonal optical electric field components (I channel and Q channel) for each polarization X and Y, according to various types of multi-value modulation methods, such as N-quadrature amplitude modulation (QAM), differential quadrature phase shift keying (D-QPSK), etc. The outputs of the QPMZ modulator arms may be fed for polarization rotation/splitting via a polarization rotator/splitter 206w for final output as Tx out. In various embodiments, the parallel sets of QPMZ components may include splitters 206t, 207t, TPSs 206h, 207h, phase shifters (e.g., high-speed phase shifters) 206g. 207g, combiners 206c, 207c, TPSs 206i, 207i, combiners 206d. 207d, VOAs 206u, 207v, MPDs 206m, 207m, and taps 206j, 207j, as shown.

FIG. 2C is a block diagram of an example implementation of a frequency discriminator 214 in accordance with various aspects described herein. In various embodiments, the frequency discriminator 214 shown in FIG. 2C may be the same as or similar to (or otherwise correspond to) any of the frequency discriminators 204 described above with respect to FIGS. 2A and 2B. Referring to FIG. 2C, the frequency discriminator 214 may include a (e.g., 3 decibel (dB)) coupler 214s that receives a tapped portion of LO in, a delay 214y on one path ‘P’ (with no similar delay in another path ‘N’), and a (e.g., 3 dB) coupler 214t that leads to two photodetectors FD_{P} and FD_{N}. Equations for current i_{P}(t) and i_{N}(t) are shown in relation to phase θ. E_{L} refers to the optical electric field of LO in, R_{P} refers to the responsivity of the photodetector FD_{P}, R_{N} refers to the responsivity of the photodetector FD_{N}, and P_{L} refers to the optical power of LO in. Responsivity of a photodetector is a measure of optical input (optical power in Watts) to electrical output (in Amperes).

In certain embodiments, the frequency discriminator 214 may be provided based on an assumption that phase is matched (and thus TPS(s) may or may not be needed). Thus, the frequency discriminator 214 may be considered an “ideal” interferometer configuration. In any case, the benefit of having separate analogue and digital P and N paths (two single-ended paths) is that the amplitude noise information (or relative intensity noise of the laser) and phase noise information may be preserved. The difference signal P−N (which a difference amplifier (described below) can output) provides the phase information, sin(θ(t−τ)−θ(t)), and rejects the amplitude noise information. |E_{L}|². The sum signal P+N (which a sum amplifier (described below) can output) provides the amplitude noise information. |E_{L}|², and rejects the phase information, sin(θ(t−τ)−θ(t)). The difference and/or the sum signals can then be used to cancel EPN and/or relative intensity noise prior to performing certain digital signal processing, such as digital dispersion compensation.

FIG. 2D is a block diagram of an example laser differential phase detection circuit 220 in accordance with various aspects described herein. As shown in FIG. 2D, the laser differential phase detection circuit 220 may include a frequency discriminator 224, an amplifier 225, and a digitizer 226. In various embodiments, the frequency discriminator 224 may be the same as or similar to (or otherwise correspond to) any of the frequency discriminators 204 described above with respect to FIGS. 2A and 2B. The frequency discriminator 224 may include a block that receives an LO in (here Pₗₒ, where P represents power), a coupler 224s, a (e.g., 90 degree) TPS 224h, a delay 224y, and a coupler 224t. Photodetectors FD_{P} and FD_{N} may receive outputs of the frequency discriminator 224 (i.e., detected phase) for amplification by the amplifier 225, which may include (e.g., difference and/or sum) amplifier device(s) 225a and a bandpass filter (BPF) 225f. The amplified phase (for difference) and/or amplified relative intensity noise (for sum) may be digitized by the digitizer 226, which may include an analog to digital converter (ADC) 226a, a delay block 226b, and an interpolator function 226i. In various embodiments, the interpolator function 226i may extract the phase noise and/or relative intensity noise and subtract some or all of these noise(s) from digitally-converted received signals, thereby reducing or eliminating EPN and/or relative intensity noise prior to equalization (such as chromatic dispersion compensation and so forth). Lin equation I(t) shown in FIG. 2D is the optical path loss measured in dB from input (Pₗₒ) to the photodetectors, FD_{P} and FD_{N}. The equation I(t) is written assuming that the optical path loss from Pₗₒ to FD_{P} and from Pₗₒ to FD_{N} are the same. The equation I(t) represents the difference current, delta I(t), of the FD_{P} output and the FD_{N} output—that is, I(t)=I_FD_{P}(t)−I_FD_{N}(t).

FIG. 2E is an example receiver circuit architecture 230 in which a transimpedance amplifier extracts phase noise in digital difference and relative intensity noise of a laser in digital sum, in accordance with various aspects described herein. As shown in FIG. 2E, the analog chain of the receiver circuit architecture 230 may include a (e.g., silicon photonics) ICR 230i, a TIA device 240, and an Rx ASIC 250. In exemplary embodiments, the ICR 230i, the TIA device 240, and the Rx ASIC 250 may be integrated with one another to provide overall EPN cancellation. In one or more embodiments, the ICR 230i, the TIA device 240, and the Rx ASIC 250 may be monolithically integrated on a single die.

In various embodiments, the ICR 230i may be the same as or similar to (or otherwise correspond to) the ICR 200a of FIG. 2A. For instance, similar to the ICR 200a, the ICR 230i in FIG. 2E may include an LO SSC 232e and a balanced receiver 232, where a frequency discriminator 234, comprising a tap 234p (e.g., ˜5% tap), splitter(s)/combiner(s) 234s (e.g., MMI or other types), TPSs 234h (which may be driven in a single-ended manner or differentially), a delay 234y (e.g., 16 mm Rib waveguide, although it will be understood that different waveguide dimensions may yield different delay/loss amounts), splitter(s)/combiner(s) 234t (e.g., MMI or other types), and (e.g., balanced) photodetectors 234d, may be configured to facilitate detection of a phase of EPN. The photodetectors 234d may be biased by a voltage V_{PD} (which may be fed from a voltage generated on the TIA device 240 or an external source).

The TIA device 240 may include various components arranged to amplify the detected phase of the EPN. In various embodiments, the TIA device 240 may include a parallel arrangement of components corresponding to the outputs of the two photodetectors 234d. For instance, as shown in FIG. 2E, the TIA device 240 may include transimpedance amplifiers 240a, 241a, feedback resistors 240k, 241k, transformers 240f, 241f, reference voltage sources 240v, 241v, direct current (DC) cancellation loops DCCp 240d, DCCn 241d, manual gain controls (MGCs) 240m, 241m (e.g., variable gain amplifiers), and output drivers (ODRs) 240r, 241r. The gain of each of the MGCs 240m, 241m may be set to any of several (e.g., four) gain values via a 2-bit digital control signal (“EPN_TZ<1:0>”). Alternatively, the gain may be set via an analog voltage or driven by a (e.g., 12 bit) digital to analog converter (DAC) to provide higher gain resolution/finesse.

A DC block 245, comprising capacitors 245c, 246c (e.g., anywhere from ˜1 nano Farad (nF) to ˜1 micro Farad (uF), depending on the desired frequency at which to start capturing the phase noise and respond to transients), may also be arranged to couple/decouple outputs of the ODRs 240r, 241r and inputs of ADCs 250a, 251a of the ASIC 250.

Inherently, the transimpedance amplifiers 240a, 241a, the MGCs 240m, 241m, the ODRs 240r. 241r may provide a low-pass function, whereas the DCCp 240d, DCCn 241d and the DC block 245 may provide a high-pass function, effectively providing a BPF (e.g., the BPF 225f of FIG. 2D).

The ADCs 250a, 251a may each be configured to sample analog signals and generate digital signals. In certain embodiments, the ADCs may be successive-approximation-register (SAR) ADCs (e.g., 1 GSs). Although the DC block 245 is shown in FIG. 2E as being separate (and possible off-chip or off-die), in alternate embodiments, the DC block 245 may be integrated with or in one of the other devices, such as front ends of the ADCs 250a and 251a. In some embodiments, the common mode voltage of the ODRs 240r. 241r may be matched (or near matched) to the common mode voltage of the ADCs 250a. 251a. In these embodiments, the DC block 245 may or may not be needed. As shown in FIG. 2E, the ASIC 250 may include an interface (e.g., a serial peripheral interface (SPI) master) for outputting data to a digital to analog converter (DAC) 231 for controlling the ICR 230i (e.g., the TPSs 234h) and/or the TIA device 240. In one or more embodiments, the SPI may output digital commands for setting the output voltage of the DAC 231, driving the TPSs 234h to hold the MZ interferometer at quadrature to maximize the signal coming out of the frequency discriminator 234. The power may be detected digitally in the ASIC 250, which may be used to dither the DAC 231 to continuously “hunt” for a maximum detected signal and balance the reported DCCn and DCCp currents, which may be read-back from the TIA (240) ADC. The SPI may output signals to the TIA 240 to control all of the RF channels and/or to control the EPN TIA's MGC “EPN_TZ<1:0>”. In some embodiments, the SPI may additionally be able to readback the DCCn and DCCp currents using the on die ADC.

It is expected that R_{P} #R_{N} and thus, the DC value of the P and N paths may be balanced and the common mode rejection ratio (CMRR) of the frequency discriminator may be optimized or improved. That is, if the responsivity of the two photodetectors FD_{P} and FD_{N} (234d) are not perfectly balanced (or if optical losses in the P and N paths are not perfectly balanced), then there might be a slight DC value that can be optimized. In such a case, the DCCn 241d may be adjusted such that the output of DCCn 241d may be made equal (or about equal) to the output of the DCCp 240d, where an additional amplifier (not shown) may be included prior to the (−) input of the MGC 240m, and where one input of the additional amplifier may take V_{IntRef} 240v and the other input of the additional amplifier may take an output of a DAC (also not shown). In this way, any such (common mode) DC value on the P and N paths may be balanced out. It is to be understood and appreciated that other circuit designs can alternatively be employed to balance such DC values.

Generally speaking, an ADC may sample analog signals periodically at a sample rate that is based on a signal received from a voltage-controlled oscillator (VCO) at the receiver device, and may apply digital signal processing to the digital signals. The digital signal processing may include equalization processing that is designed to compensate for a variety of channel impairments, such as CD, SOP rotation, mean PMD that determines the probability distribution which instantiates as differential group delay (DGD), PDL or PDG, and/or other effects. The digital signal processing may further include carrier recovery processing, which may include calculating an estimate of carrier frequency offset fIF (i.e., the difference between the frequency of the transmitter laser and the frequency of the receiver laser). According to some example implementations, the digital signal processing may further include multiple-input-multiple-output (MIMO) filtering, clock recovery, and FDM subcarrier de-multiplexing. The digital signal processing may include symbol-to-bit demapping (or decoding) using a decision circuit, such that signals resulting from the digital signal processing are representative of bit estimates. Where a received optical signal is representative of symbols comprising FEC-encoded bits generated as a result of applying FEC encoding to client bits, the signals may further undergo FEC decoding to recover the corrected client bits.

In any case, the configuration of FIG. 2E may provide both the above-discussed difference signal P−N, which yields the phase information, sin(θ(t−τ)−θ(t)), and the above-discussed sum signal P+N, which yields the amplitude noise information (or relative intensity noise of the laser), |E_{L} 12.

FIG. 2F is an example receiver circuit architecture 230′ in which a transimpedance amplifier extracts (e.g., only) phase noise in digital difference, in accordance with various aspects described herein. The analog chain of the receiver circuit architecture 230′ may include a (e.g., silicon photonics) ICR 230i, a TIA device 240′, and an Rx ASIC 250′. In various embodiments, the TIA device 240′ may be similar to or otherwise correspond to the TIA device 240 of FIG. 2E, and the Rx ASIC 250′ may be similar to or otherwise correspond to the Rx ASIC 250 of FIG. 2E. The differences here are that the TIA device 240′ may not include MGC 241m and ODR 241r, the output of the amplifier 241a of the TIA device 240′ may be additionally fed to an input of the MGC 240m, the ASIC 250′ may not include ADC 251a, and DC block 245′ may not include capacitors 246c. The configuration of FIG. 2F may provide the above-discussed difference signal P−N, which yields the phase information, sin(θ(t−τ)−θ(t)), and rejects the amplitude noise information (or relative intensity noise of the laser), |E_{L}|².

FIG. 2G shows a high-level architecture of a modem receiver 230r with example flows between components, in accordance with various aspects described herein. As shown in FIG. 2G, the modem receiver 230r may include a receiver assembly 230v (which may be implemented via flip chip or otherwise). In various embodiments, the modem receiver 230r may include or incorporate some or all of the components described above with respect to one or more of FIGS. 2A, 2C, 2D, 2E and 2F. For instance, as shown, the receiver assembly 230v may comprise a (e.g., SiP) package 230i that includes the ICR 232, the tap coupler 234p, the interferometer-based balanced phase discriminator 234 with balanced photodetectors 234d (FD_{P} and FD_{N}), and a main receiver path 2320 with polarization splitting element(s) 232r, 232s, 232t (e.g., similar to or corresponding to 202r, 202s, 202t of FIG. 2A), hybrid mixers X. Y (e.g., similar to optical hybrids X. Y of FIG. 2A), and HSPDs 232p (e.g., similar to HSPDs 202p of FIG. 2A).

Additionally, the receiver assembly 230v may comprise TIA(s) 242 and an ASIC 252 for amplifying, obtaining a difference of, and digitizing/demodulating signals for the main receive path 2320. Further, the receiver assembly 230v may comprise TIA(s) 240a, 241a as well as ASIC 250′ (with ADC 250a) for estimating and digitizing the phase noise information. Furthermore, the receiver assembly 230v may comprise TIA(s) 240d, 241d for digital sampling of DC currents (e.g., DCCp, DCCn of FIG. 2F) of the balanced photodetectors 234d, and an ASIC 253 that uses such sampling to control the DAC 231 for driving the phase shifters 234h of the interferometer-based balanced phase discriminator 234. An ASIC 254 may apply the extracted phase to the digital communications signal of the main receiver path 2320 prior to digital dispersion processing, thereby reducing or eliminating EEPN. It will be understood and appreciated that some or all of the ASICs 250′, 252, 253, and 254 may be implemented individually or in a combined manner. For instance, a single ASIC may include multiple ADCs that provide various of the above-described ASIC-related functions.

It is to be understood and appreciated that, although one or more of FIGS. 1 and 2A-2G might be described above as pertaining to various processes and/or actions that are performed in a particular order, some of these processes and/or actions may occur in different orders and/or concurrently with other processes and/or actions from what is depicted and described above. Moreover, not all of these processes and/or actions may be required to implement the systems and/or methods described herein. Furthermore, while various components, devices, systems, modules, circuits, etc. have been illustrated in one or more of FIGS. 2A-2D as separate components, devices, systems, modules, circuits, etc., it will be appreciated that multiple components, devices, systems, modules, circuits, etc. can be implemented as a single component, device, system, module, circuit, etc., or a single component, device, system, module, circuit, etc. can be implemented as multiple components, devices, systems, modules, circuits, etc. Additionally, functions described as being performed by one component, device, system, module, circuit, etc. may be performed by multiple components, devices, systems, modules, circuits, etc., or functions described as being performed by multiple components, devices, systems, modules, circuits, etc. may be performed by a single component, device, system, module, circuit, etc.

The terms “first,” “second,” “third,” and so forth, as used in the claims, unless otherwise clear by context, is for clarity only and does not otherwise indicate or imply any order in time. For instance, “a first determination,” “a second determination,” and “a third determination,” does not indicate or imply that the first determination is to be made before the second determination, or vice versa, etc.

In the subject specification, terms such as “store,” “storage,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can comprise both volatile and nonvolatile memory, by way of illustration, and not limitation, volatile memory, non-volatile memory, disk storage, and memory storage. Further, nonvolatile memory can be included in read only memory (ROM), programmable ROM (PROM), electrically programmable ROM (EPROM), electrically erasable ROM (EEPROM), or flash memory. Volatile memory can comprise random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

As used in some contexts in this application, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, computer-executable instructions, a program, and/or a computer. As yet another example, a component can be an apparatus that provides specific functionality through electronic components without mechanical parts, the electronic components can comprise a processor therein to execute software or firmware that confers at least in part the functionality of the electronic components. While various components have been illustrated as separate components, it will be appreciated that multiple components can be implemented as a single component, or a single component can be implemented as multiple components, without departing from example embodiments. Additionally, functions described as being performed by one component or system may be performed by multiple components or systems, or functions described as being performed by multiple components or systems may be performed by a single component or system, without departing from example embodiments.

Further, the various embodiments can be implemented as a method, apparatus or article of manufacture using standard programming and/or engineering techniques to produce software, firmware, hardware or any combination thereof to control a computer to implement the disclosed subject matter. The term “article of manufacture” as used herein is intended to encompass a computer program accessible from any computer-readable device or computer-readable storage/communications media. For example, computer readable storage media can include, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A device, comprising:
an optical package;
a frequency discriminator configured to provide complementing signals that include phase noise associated with a local oscillator (LO) input;
a transimpedance amplifier (TIA) system adapted to provide one or more phase information signals by amplifying a difference of the complementing signals; and
an application specific integrated circuit (ASIC) configured to process the one or more phase information signals to derive an estimation of the phase noise, wherein the frequency discriminator is implemented in the optical package and integrated with the TIA system and the ASIC to facilitate avoidance of enhanced equalized phase noise (EEPN).

2. The device of claim 1, wherein the frequency discriminator, the TIA system, and the ASIC are monolithically integrated on a same die.

3. The device of claim 1, wherein the optical package comprises a silicon photonics (SiP) intradyne coherent receiver (ICR) package with a balanced receiver.

4. The device of claim 1, wherein the optical package comprises a transmit receive optical silicon integrated circuit (TROSiC) package with a balanced receiver and a quad parallel Mach-Zehnder (QPMZ) modulator, and wherein the LO input is split between the balanced receiver and the QPMZ modulator.

5. The device of claim 1, wherein the frequency discriminator feeds from a tap coupler on a LO input path in the optical package.

6. The device of claim 1, wherein the frequency discriminator is interferometer-based.

7. The device of claim 1, wherein the frequency discriminator comprises a delay element arranged in one of two paths, resulting in a delayed path and a non-delayed path.

8. The device of claim 1, wherein the frequency discriminator comprises a splitter device that manipulates a portion of the LO input for output onto two paths.

9. The device of claim 8, wherein a ratio of the splitter device is other than 50/50.

10. The device of claim 1, wherein the frequency discriminator comprises one or more phase shifters for controlling phase in two paths.

11. The device of claim 1, wherein the frequency discriminator comprises a combiner device that couples a delayed path and a non-delayed path to a pair of balanced photodetectors.

12. The device of claim 11, wherein a ratio of the combiner device is 50/50.

13. The device of claim 1, wherein the complementing signals comprise an inverting signal and a non-inverting signal.

14. The device of claim 1, wherein the ASIC or another ASIC of the device is configured to:
digitize the estimation of the phase noise, resulting in a digitized estimation; and
process a digital conversion of a received signal with the digitized estimation prior to performing digital dispersion compensation so as to reduce or eliminate the EEPN.

15. The device of claim 1, wherein the ASIC comprises a successive-approximation-register (SAR) analog to digital converter (ADC).

16. The device of claim 1, further comprising a second TIA system adapted to provide a voltage signal or a digitally sampled representation of the voltage signal for use by the ASIC or another ASIC to drive phase shifters of the frequency discriminator.

17. The device of claim 1, wherein the complementing signals further include relative intensity noise associated with the LO input, wherein the TIA system is further adapted to provide one or more relative intensity noise information signals by amplifying a sum of the complementing signals, and wherein the ASIC or another ASIC is configured to process the one or more relative intensity noise information signals to derive an estimation of the relative intensity noise.

18. A noise cancellation system for facilitating avoidance of enhanced equalized phase noise (EEPN), the noise cancellation system comprising:
a frequency discriminator configured to provide complementing signals that include phase noise associated with a local oscillator (LO) input;
a transimpedance amplifier (TIA) system adapted to provide one or more phase information signals by amplifying a difference of the complementing signals; and
an application specific integrated circuit (ASIC) configured to process the one or more phase information signals to derive an estimation of the phase noise, wherein the frequency discriminator is implemented in an optical package and integrated with the TIA system and the ASIC.

19. The noise cancellation system of claim 18, wherein the frequency discriminator is interferometer-based.

20. A method, comprising:
implementing a frequency discriminator in an optical package, the frequency discriminator being configured to provide complementing signals that include phase noise associated with a local oscillator (LO) input; and
integrating a transimpedance amplifier (TIA) system and an application specific integrated circuit (ASIC) with the frequency discriminator to facilitate avoidance of enhanced equalized phase noise (EEPN),
wherein the TIA system is adapted to provide one or more phase information signals by amplifying a difference of the complementing signals, and
wherein the ASIC is configured to process the one or more phase information signals to derive an estimation of the phase noise.
